(19) United States
(12) Patent Application Publication
(10) Pub. No.: US 2008/0115349 A1
(43) Pub. Date: May 22, 2008

(54) Method of manufacturing a component-embedded printed circuit board

(75) Inventors: Seung-Gu Kim, Suwon-si (KR); Je-Gwang Yoo, Yongin-si (KR); Doo-Hwan Lee, Suwon-si (KR); Moon-Il Kim, Yuseong-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/984,210

(22) Filed: Nov. 14, 2007

(30) Foreign Application Priority Data
Nov. 21, 2006 (KR) 10-2006-0115399

(51) Int. Cl. H05K 3/30; H05K 3/36; H05K 3/20

(52) U.S. Cl. 29/830; 29/832; 29/831; 29/852

(57) ABSTRACT

A method of manufacturing a component-embedded printed circuit board component is disclosed. With a method of manufacturing a component-embedded printed circuit board that includes: perforating a through-hole in a core substrate, on a surface of which a circuit pattern is formed, attaching tape to one side of the core substrate and attaching a component onto the tape exposed in the through-hole, filling adhesive in a portion of the gap between the through-hole and the component to secure the component, removing the tape, and collectively stacking insulation on both sides of the core substrate to fill the remainder of the gap between the through-hole and the component with portions of the insulation, the component may be embedded using a minimal amount of heterogeneous materials, so that the warpage of the board may be prevented

### CROSS-REFERENCE TO RELATED APPLICATIONS

This application claims the benefit of Korean Patent Application No. 10-2006-0115399 filed with the Korean Intellectual Property Office on Nov. 21, 2006, the disclosure of which is incorporated herein by reference in its entirety.

### BACKGROUND

1. Technical Field

The present invention relates to a method of manufacturing a component-embedded printed circuit board.

2. Description of the Related Art

With the decrease in size of portable electronic devices, so also is the area for mounting electronic components decreasing. Some conventional IC packages had the form of 3D packages, in which passive components and active components were piled upwards for greater densities. This form of IC package was effective to a certain degree in reducing the area for mounting.

However, as there is a limit to decreasing size when using surface-mounting, active or passive components may be embedded within the board to implement higher densities in smaller sizes. A typical method of manufacturing a component-embedded type board is as follows.

First, a through-hole is perforated in a copper clad laminate in the position where an electronic component is to be embedded. Then, tape is attached at one side of the through-hole, and the electronic component is attached to the adhesive surface of the tape exposed inside the through-hole. Next, the remaining portions of the through-hole are filled with a filler, and when the filler is cured, the tape is removed. At the surface where the tape is removed, the electrical contacts of the electrical component are exposed, and to connect the exposed contacts with the circuit patterns, the processes of electroless plating and electroplating are performed. The electroless plating is added because the filler is non-conductive. After the plating process, the process of forming circuit patterns is performed.

However, in the above process, when the through-hole is filled with a filler after inserting the component in the through-hole, heterogeneous materials are placed in contact with each other, so that undesired effects may occur, such as warpage of the board due to physical changes in its surroundings.

### SUMMARY

An aspect of the invention is to provide a method of manufacturing a component-embedded printed circuit board which entails a minimal use of heterogeneous materials, so that warpage is minimized in the board even when components are embedded.

One aspect of the claimed invention provides a method of manufacturing a component-embedded printed circuit board that includes: perforating a through-hole in a core substrate, on a surface of which a circuit pattern is formed, attaching tape to one side of the core substrate and attaching a component onto the tape exposed in the through-hole, filling adhesive in a portion of the gap between the through-hole and the component to secure the component, removing the tape, and collectively stacking insulation on both sides of the core substrate to fill the remainder of the gap between the through-hole and the component with portions of the insulation.

After collectively stacking the insulation, an operation of forming a circuit pattern on a surface of the insulation may further be included.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a component-embedded printed circuit board according to an embodiment of the invention.

FIG. 2 is a process diagram illustrating a method of manufacturing a component-embedded printed circuit board according to an embodiment of the invention.

FIG. 3 and FIG. 4 are plan views of component-embedded printed circuit boards according to certain embodiments of the invention.

### DETAILED DESCRIPTION

Embodiments of the invention will be described below in more detail with reference to the accompanying drawings. In the description with reference to the accompanying drawings, those components are rendered the same reference number that are the same or are in correspondence regardless of the figure number, and redundant explanations are omitted.

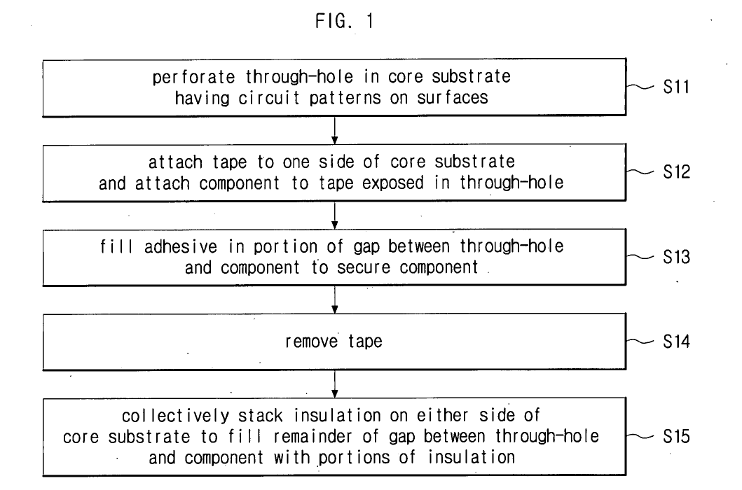

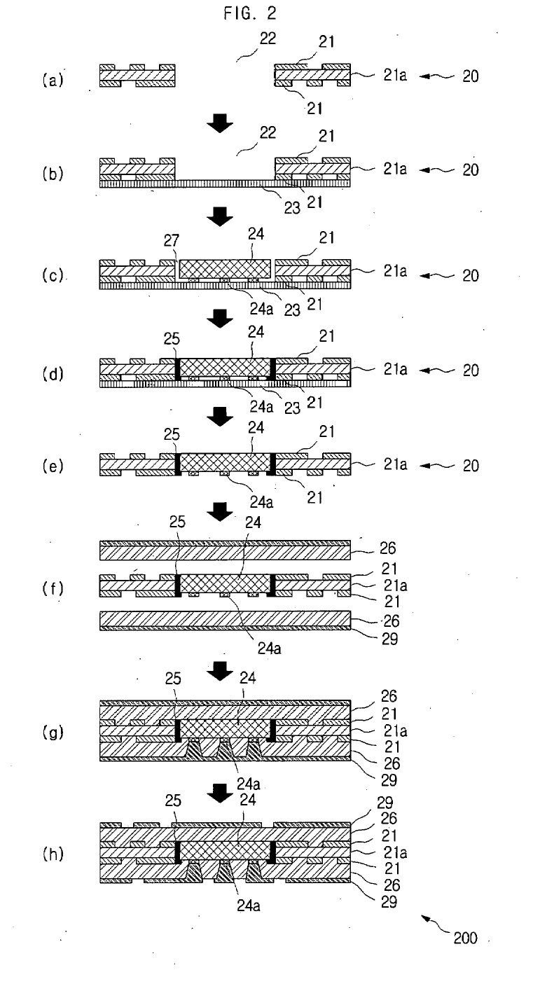

FIG. 1 is a flowchart illustrating a method of manufacturing a component-embedded printed circuit board according to an embodiment of the invention, and FIG. 2 is a process diagram illustrating a method of manufacturing a component-embedded printed circuit board according to an embodiment of the invention. In FIG. 2 are illustrated a core substrate 20, an insulation layer 21a, circuit patterns 21, 29, a through-hole 22, tape 23, a component 24, pads 24a, adhesive 25, and insulation 26.

Operation S11 of FIG. 1 represents perforating a through-hole 22 in a core substrate 20 having a circuit pattern 21 is formed on a surface, and drawing (a) of FIG. 2 illustrates a corresponding process. The core substrate 20 may have the form of an insulation layer 21a on the surfaces of which circuit patterns 21 are formed. The circuit pattern 21 may be formed by a general process, such as a subtractive or semi-additive process, etc. The through-hole 22 may be perforated in the core substrate 20 after selecting the position where the component 24 is to be mounted. The perforation method may involve using a mechanical drill.

Operation S12 of FIG. 1 represents attaching tape to one side of the core substrate 20 and attaching a component 24 onto the tape 23 exposed in the through-hole 22, and drawings (b) and (c) of FIG. 2 illustrate the corresponding processes. The tape 23 may be a material that closes one side of the through-hole 22, and then temporarily secures the component 24 before the component 24 is secured by adhesive 25. The component 24 may be inserted in the through-hole 22, where it may be inserted such that the pads 24a are in contact with the tape 23.

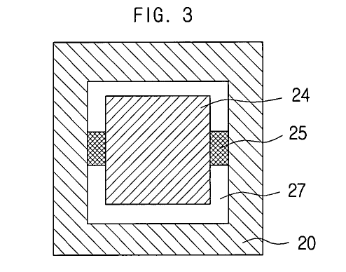

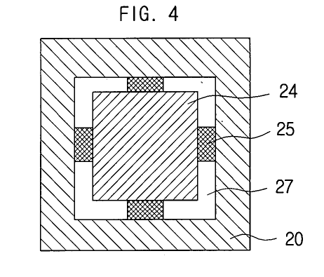

Operation S13 of FIG. 1 represents filling adhesive 25 in a portion of the gap 27 between the through-hole 22 and the component 24 to secure the component 24, and operation S14 represents removing the tape 23, with drawings (d) and (e) of FIG. 2 illustrating the corresponding processes. The adhesive 25 may be of a material different from that of the insulation layer 21a, which may cause the board to be warped when exposed to external heat, since heterogeneous materials have different coefficients of thermal expansion. This may incur adverse effects on the reliability of a product. Therefore, it is important to minimize contact between such heterogeneous materials. The adhesive 25, in this process, may secure the component 24 in the through-hole 22 for only a particular amount of time. Thus, the gap between the component 24 and the through-hole 22 does not have to be fully filled with the adhesive 25, and only a certain amount may be used which can temporarily secure the component 24. As such, the adhesive 25 is filled in only a portion of the gap 27. When the component 24 is secured as in the present embodiment, there is less use of adhesive 25, so that those problems that may occur between heterogeneous materials may be reduced. FIG. 3 and FIG. 4 illustrate filling adhesive 25 in the gap 27 at two points and at four points, respectively, to secure the component 24.

When the adhesive 25 is sufficiently cured, the tape 23 may be removed. The tape 23 may be a temporary material for securing the component 24 in the perforated hole 22, and thus may be removed for subsequent processes.

Operation S15 of FIG. 1 represents collectively stacking insulation 26 on both sides of the core substrate 20 to fill the remainder of the gap 27 between the through-hole 22 and the component 24 with portions of the insulation 26, and drawings (f) and (g) of FIG. 2 illustrate the corresponding processes. The insulation 26 may have a high content of resin, which has relatively good flow characteristics. Thus, when thermal pressing is applied, the resin, i.e. portions of the insulation 26, may flow into and fill the remainder of the gap 27. Afterwards, when the temperature is lowered, the insulation 26 may be cured, as well as the resin flowed into the gap 27, whereby the component 24 may be secured in a stable manner.

Afterwards, as in (h) of FIG. 2, circuit patterns 29 may additionally be formed on the surfaces of the insulation 26.

According to certain embodiments of the invention as set forth above, a component can be embedded in a printed circuit board using a minimal amount of adhesive, so that warpage of the board, which may occur when embedding a component using heterogeneous materials, can be prevented.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a component-embedded printed circuit board, the method comprising:
perforating at least one through-hole in a core substrate having a circuit pattern formed on at least one surface thereof;
attaching tape to one side of the core substrate, and attaching a component onto the tape exposed in the through-hole;
filling adhesive in a portion of a gap between the through-hole and the component to secure the component;
removing the tape; and
collectively stacking insulation on both sides of the core substrate to fill a remainder of the gap between the through-hole and the component with a portion of the insulation.

2. The method of claim 1, further comprising, after the collective stacking, forming a circuit pattern on a surface of the insulation.
